(19) United States
(12) Patent Application Publication
(10) Pub. No.: US 2024/0298456 A1
(43) Pub. Date: Sep. 5, 2024

(54) QUANTUM DOT LIGHT-EMITTING DEVICE AND MANUFACTURING METHOD THEREFOR, AND DISPLAY APPARATUS

(71) Applicant: BOE Technology Group Co., Ltd., Beijing (CN)

(72) Inventor: Yang GAO, Beijing (CN)

(21) Appl. No.: 18/261,711

(22) PCT Filed: Feb. 10, 2021
(86) PCT No.: PCT/CN2021/076534

§ 371 Date: Jul. 17, 2023

(51) Int. Cl. H10K 50/115; B82Y 20/00; C09K 11/02; C09K 11/88; H10K 50/15; H10K 50/16; H10K 50/18; H10K 50/85; H10K 71/12

(52) U.S. Cl. CPC H10K 50/115; C09K 11/025; C09K 11/883; H10K 50/15; H10K 50/16; H10K 50/18; H10K 50/181; H10K 50/85; H10K 71/12; B82Y 20/00

(57) ABSTRACT

Disclosed in the embodiments of the present disclosure are a quantum dot light-emitting device and a manufacturing method therefor, and a display apparatus. The quantum dot light-emitting device comprises: an anode and a cathode, which are arranged opposite each other; a light-emitting layer located between the anode and the cathode; a hole transport layer located between the anode and the light-emitting layer; and an electron transport layer located between the cathode and the light-emitting layer, wherein the light-emitting layer comprises: a plurality of first phases arranged independently of each other and a second phase located between the first phases, and each of the first phases comprises a first polymer and a quantum dot material.

### CROSS REFERENCE TO RELATED APPLICATIONS

This application is a national phase entry under 35 U.S.C. § 371 of International Application No. PCT/CN2021/076534, filed on Feb. 10, 2021, the entire content of which is incorporated herein by reference.

### TECHNICAL FIELD

The present disclosure relates to the field of display technology, in particular to a quantum dot light-emitting device and a manufacturing method therefor, and a display apparatus.

### BACKGROUND

Quantum dots (QDs), also known as semiconductor nanocrystals or semiconductor nanoparticles, refer to nano-sized solid materials of which a size is on the order of nanometers in three dimensions in space or composed of quantum dots as a basic unit, and are a collection of atoms and molecules on the nanometer scale. Light-emitting diodes based on quantum dot materials are known as quantum dot light-emitting diodes (QLEDs), which are a new type of light-emitting devices.

### SUMMARY

An embodiment of the present disclosure provides a quantum dot light-emitting device, including: an anode and a cathode which are oppositely disposed, a light-emitting layer between the anode and the cathode, a hole transport layer between the anode and the light-emitting layer, and an electron transport layer between the cathode and the light-emitting layer. Where the light-emitting layer includes: a plurality of first phases arranged independent from each other, and a second phase between the first phases; and the first phase includes a first polymer and a quantum dot material.

Optionally, in the above quantum dot light-emitting device provided by the embodiment of the present disclosure, the second phase includes a second polymer, and a refractive index of the first phase is greater than a refractive index of the second phase.

Optionally, in the above quantum dot light-emitting device provided by the embodiment of the present disclosure, the anode or the cathode is a reflection electrode, and a refractive index of the hole transport layer and a refractive index of the electron transport layer are both approximately the same as a refractive index of the second phase.

Optionally, in the above quantum dot light-emitting device provided by the embodiment of the present disclosure, a material of the second polymer is the same as a material of the hole transport layer, or a material of the second polymer is a hole transport material, or the second polymer is doped with a material that facilitates hole transport. The quantum dot light-emitting device further includes an electron blocking layer between the light-emitting layer and the electron transport layer.

Optionally, in the above quantum dot light-emitting device provided by the embodiment of the present disclosure, the material of the second polymer includes poly(9,9-dioctylfluorene-co-N-(4-butylphenyl)diphenylamine), poly[N,N′-bis(4-butylphenyl)-N,N′-bis(phenyl)-benzi], polyphenylene vinylene or poly(9-vinylcarbazole); or a doping material in the second polymer includes 4,4′-bis(N-carbazole)-1,1′-biphenyl.

Optionally, in the above quantum dot light-emitting device provided by the embodiment of the present disclosure, a material of the electron blocking layer includes polyethylene, polypropylene, polytetrafluoroethylene, polycarbonate, polyamide, polymethyl methacrylate, alumina or silica.

Optionally, in the above quantum dot light-emitting device provided by the embodiment of the present disclosure, a material of the second polymer is the same as a material of the electron transport layer, or a material of the second polymer is an electron transport material, or the second polymer is doped with a material that facilitates electron transport. The quantum dot light-emitting device further includes a hole blocking layer between the light-emitting layer and the hole transport layer.

Optionally, in the above quantum dot light emitting device provided by the embodiment of the present disclosure, a doping material in the second polymer includes 4,7-diphenyl-1,10-phenanthroline, 1,3,5-tris(1-phenyl-1H-benzimidazol-2-yl)benzene, 2,8-bis(diphenylphosphoryl)dibenzofuran, and 1,3,5-tris[(3-pyridyl)-3-phenyl]benzene.

Optionally, in the above quantum dot light-emitting device provided by the embodiment of the present disclosure, a material of the hole blocking layer includes polyethylene, polypropylene, polytetrafluoroethylene, polycarbonate, polyamide, polymethyl methacrylate, alumina or silica.

Optionally, in the above quantum dot light-emitting device provided by the embodiment of the present disclosure, the second phase further includes nanoparticles, and the nanoparticles are configured to generate localized surface plasmon resonance under irradiation by light of a preset wavelength.

Optionally, in the above quantum dot light-emitting device provided by the embodiment of the present disclosure, the nanoparticles are metal nanoparticles, the light-emitting layer has a plurality of sub-pixels of different light-emitting colors, each of the sub-pixels includes quantum dot materials of the same color, and the quantum dot materials of different colors correspond to different sizes of the same metal nanoparticles.

Optionally, in the above quantum dot light-emitting device provided by the embodiment of the present disclosure, the light-emitting layer includes a first sub-pixel emitting red light, a second sub-pixel emitting green light, and a third sub-pixel emitting blue light. The first sub-pixel includes a red quantum dot material, the second sub-pixel includes a green quantum dot material, and the third sub-pixel includes a blue quantum dot material. The particle size of the metal nanoparticle to which the red quantum dot material corresponds, the particle size of the metal nanoparticle to which the green quantum dot material corresponds, and the particle size of the metal nanoparticle to which the blue quantum dot material corresponds decrease sequentially.

Optionally, in the above quantum dot light-emitting device provided by the embodiment of the present disclosure, a material of the nanoparticles includes at least one of Ag, Au, Pt, Pd, Cu or Al.

Optionally, in the above quantum dot light-emitting device provided by the embodiment of the present disclosure, a material of the second polymer includes a crosslinked polymeric material or a polymeric material with a melting point greater than a preset value.

Optionally, in the above quantum dot light-emitting device provided by the embodiment of the present disclosure, a cross-sectional shape of the first phase includes a square, an inverted trapezoid or a curved surface shape along a direction perpendicular to the cathode.

Optionally, in the above quantum dot light-emitting device provided by the embodiment of the present disclosure, the quantum dot material is a hydrophobic material, the first polymer is a hydrophobic material, and the second polymer is a hydrophilic material. Or, the quantum dot material is a hydrophilic material, the first polymer is a hydrophilic material, and the second polymer is a hydrophobic material.

Optionally, in the above quantum dot light-emitting device provided by the embodiment of the present disclosure, the quantum dot material has a hydrophobic ligand, where the hydrophobic ligand includes a coordination group that coordinates with the quantum dots, and an alkane group connected with the coordination group; and the first polymer includes polystyrene, and the second polymer includes polyethylene oxide, polymethyl methacrylate, polyacrylate or polyamide. Or, the quantum dot material has a hydrophilic ligand, where the hydrophilic ligand includes a coordination group that coordinates with the quantum dots, an alkane group connected with the coordination group, and a hydrophilic group connected with the alkane group, where the hydrophilic group includes hydroxy, amino, mercapto, carboxyl or a sulfonic acid group; and the first polymer includes polyethylene oxide, polymethyl methacrylate, polyacrylate or polyamide, and the second polymer includes polyolefin or polystyrene.

Optionally, in the above quantum dot light-emitting device provided by the embodiment of the present disclosure, in the first phase, the quantum dot material is bonded to at least part of the first polymer through coordination bonds; and the second polymer and the quantum dot material are unable to be subjected to coordination binding.

Optionally, in the above quantum dot light-emitting device provided by the embodiment of the present disclosure, the first polymer includes a side chain having hydroxy, carboxyl, amino or mercapto.

Correspondingly, an embodiment of the present disclosure further provides a manufacturing method for the above quantum dot light-emitting device, including: forming an anode and a cathode which are oppositely disposed, forming a light-emitting layer between the anode and the cathode, forming a hole transport layer between the anode and the light-emitting layer, and forming an electron transport layer between the cathode and the light-emitting layer. Where forming the light-emitting layer specifically includes: dissolving a first polymer and a second polymer in a preset solvent to obtain a solution of the first polymer and the second polymer; adding a quantum dot material to the solution of the first polymer and the second polymer to be completely mixed to prepare a mixed solution of the first polymer, the second polymer and the quantum dot material; and forming a film layer of the mixed solution on a front film layer, and volatilizing the solvent to form a light-emitting layer having a plurality of first phases, and the second phase between the first phases.

Correspondingly, an embodiment of the present disclosure further provides a display apparatus, including the above quantum dot light-emitting device.

### BRIEF DESCRIPTION OF FIGURES

FIG. 1 shows a schematic structural diagram of a quantum dot light-emitting device provided by an embodiment of the present disclosure.

FIG. 2 shows a top view of a light-emitting layer in FIG. 1.

FIG. 3 shows a schematic diagram for illustrating a light-emitting principle of the light-emitting layer in FIG. 1.

FIG. 4 shows a schematic structural diagram of yet another quantum dot light-emitting device provided by an embodiment of the present disclosure.

FIG. 5 shows a schematic structural diagram of a quantum dot light-emitting device provided by an embodiment of the present disclosure.

FIG. 6 shows a schematic diagram for illustrating an electron-hole transport principle corresponding to FIG. 5.

FIG. 7 shows a schematic structural diagram of yet another quantum dot light-emitting device provided by an embodiment of the present disclosure.

FIG. 8 shows a schematic diagram for illustrating an electron-hole transport principle corresponding to FIG. 7.

FIG. 9 shows a schematic structural diagram of yet another quantum dot light-emitting device provided by an embodiment of the present disclosure.

FIG. 10 shows a schematic diagram for illustrating degradation of a light-emitting layer in a quantum dot light-emitting device provided by an embodiment of the present disclosure.

FIG. 11 shows a schematic diagram of degradation of a light-emitting layer in a quantum dot light-emitting device in the related art.

FIG. 12 shows a schematic diagram of yet another light-emitting principle of the light-emitting layer of FIG. 1.

FIG. 13 shows a schematic diagram for illustrating yet another light-emitting principle of the light-emitting layer of FIG. 1.

FIG. 14 shows a schematic structural diagram of yet another quantum dot light-emitting device provided by an embodiment of the present disclosure.

FIG. 15 shows a schematic structural diagram of yet another quantum dot light-emitting device provided by an embodiment of the present disclosure.

FIG. 16 shows a schematic structural diagram of yet another quantum dot light-emitting device provided by an embodiment of the present disclosure.

FIG. 17 shows a schematic structural diagram of yet another quantum dot light-emitting device provided by an embodiment of the present disclosure.

FIG. 18 shows a schematic diagram of a quantum dot material, a first phase and a second phase in a light-emitting layer.

FIG. 19 shows a schematic diagram of yet another quantum dot material, a first phase, and a second phase in a light-emitting layer.

FIG. 20 shows a schematic flow chart of a manufacturing method for a light-emitting layer in a quantum dot light-emitting device.

### DETAILED DESCRIPTION

In order to make objectives, technical solutions and advantages of the embodiments of the present disclosure clearer, the technical solutions of the embodiments of the present disclosure are described clearly and completely below with reference to the drawings of the embodiments of the present disclosure. Apparently, the described embodiments are some, not all, of the embodiments of the present disclosure. The embodiments in the present disclosure and the features in the embodiments may be combined with each other without conflict. Based on the described embodiments of the present disclosure, all other embodiments obtained by those of ordinary skill in the art without inventive efforts fall within the protection scope of the present disclosure.

Unless otherwise indicated, the technical or scientific terms used in the present disclosure shall have the ordinary meaning as understood by those of ordinary skill in the art to which the present disclosure belongs. Similar words such as “including” or “comprising” used in the present disclosure mean that an element or item preceding the word covers elements or items listed behind the word and their equivalents without excluding other elements or items. “Connection” or “connected” and other similar words may include electrical connection, whether direct or indirect, instead of being limited to physical or mechanical connection. “Inner”, “outer”, “upper”, “lower” and the like are only used to indicate a relative positional relationship, and the relative positional relationship may change accordingly when an absolute position of the described object changes.

It should be noted that sizes and shapes of all figures in the drawings do not reflect a true scale and are only intended to illustrate the contents of the present disclosure. Same or similar reference signs denote same or similar elements or elements with the same or similar function throughout.

The external quantum efficiency (EQE) of a QLED device is a product of the internal quantum efficiency (IQE) and the light extraction efficiency (LEE) η_{out-coupling} of the device, and the light extraction efficiency is defined as a ratio of the number of photons emitted from the device to the number of photons generated by the light-emitting layer of the device. Increasing the light extraction efficiency is of great importance for improving the external quantum efficiency EQE of the QLED device.

For the light emitted from the light emitting layer of the QLED device, there are different types of consumption, such as absorption, a waveguide mode, surface plasmon polariton (SPP) dissipation, etc., resulting in only a very small amount of light (typically less than 30%) ultimately emitting from the device. Improving the light extraction efficiency of the device requires optical design of the multiple layers of the device, including matching of a refractive index and the thickness between the respective layers, reducing quenching of excitons by electrodes, and the like.

At present, in the existing QLED device structure, the light-emitting layer is generally a uniformly flat layer, and after excitons in QDs are recombined to emit light, some light cannot be emitted from the device because it is limited to propagate in the light-emitting layer due to the presence of the optical waveguide mode, thereby reducing the light extraction efficiency of the device, resulting in waste of light emission.

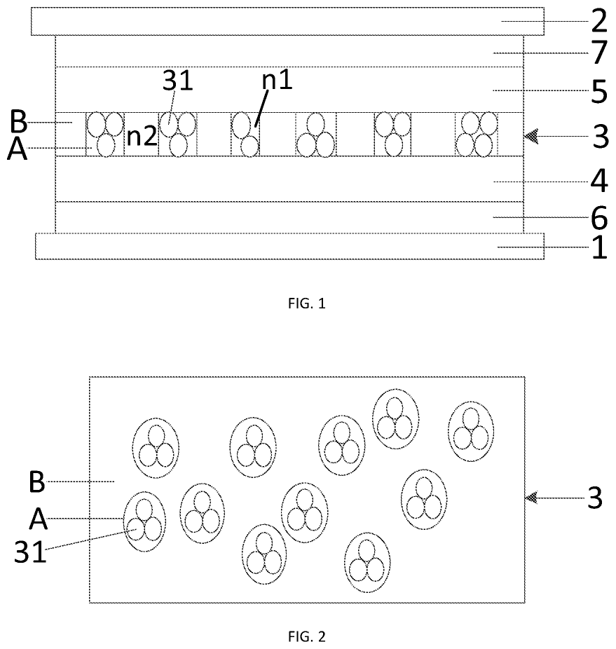

In view of this, an embodiment of the present disclosure provides a quantum dot light-emitting device, as shown in FIGS. 1 and 2, FIG. 1 shows a cross-sectional view of a quantum dot light-emitting device, and FIG. 2 shows a top view of a light-emitting layer in FIG. 1, and the quantum dot light-emitting device includes: an anode 1 and a cathode 2 which are disposed in opposite, a light-emitting layer 3 between the anode 1 and the cathode 2, a hole transport layer 4 between the anode 1 and the light-emitting layer 3, and an electron transport layer 5 between the cathode 2 and the light-emitting layer 3.

The light-emitting layer 3 includes: a plurality of first phases A independent from each other, and a second phase B between the first phases A.

The first phase A includes a first polymer and a quantum dot material 31.

In the embodiment of the present disclosure, since aggregates of the quantum dot material 31 in the respective first phases A in the light-emitting layer 3 are separated from each other, exciton quenching or interaction between other excitons caused by energy transfer among the quantum dot materials 31 can be effectively reduced, non-radiative recombination pathways of excitons can be reduced, the light-emitting quantum yield of the quantum dot light-emitting device can be improved, and the external quantum efficiency of the QLED device can be further improved.

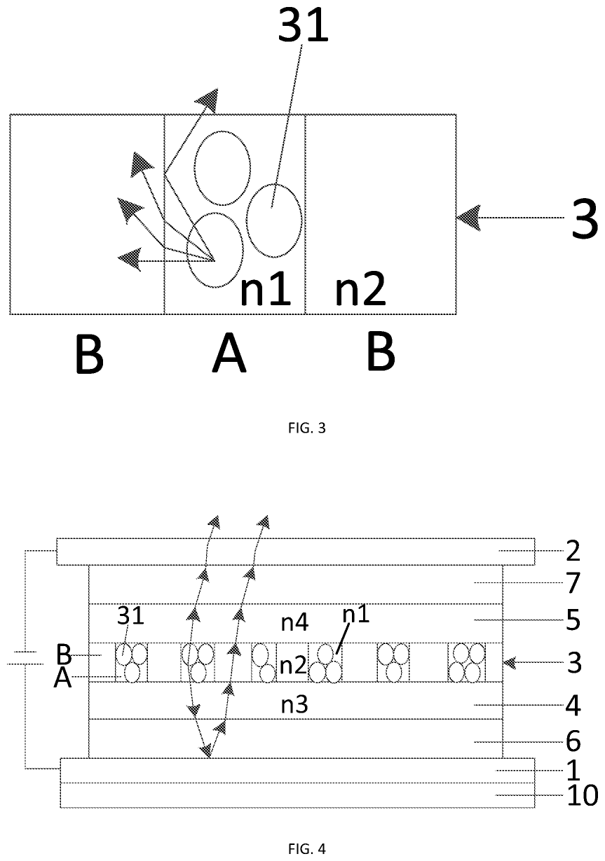

In specific implementation, in the above quantum dot light-emitting device provided by the embodiment of the present disclosure, as shown in FIG. 1, the second phase B includes a second polymer, and a refractive index n1 of the first phase is greater than a refractive index n2 of the second phase. In the present disclosure, the light-emitting layer 3 having a two-phase structure of the first phase A (which is a dispersed phase) and the second phase B (which is a continuous phase) is manufactured, the quantum dot material 31 is aggregated in the first phase A, and it is ensured that the refractive index n1 of the first phase A is greater than the refractive index n2 of the second phase B. According to the law of refraction of light, for light emitted by the quantum dot material 31 of the light-emitting layer 3, only light having an incident angle (an angle between incident light and a normal of an interface between the first phase A and the second phase B) less than a critical angle arcsin(n2/n1) can enter the second phase B from the first phase A, and thus be easily lost due to continuous propagation within the light-emitting layer 3. When the incident angle is greater than or equal to arcsin(n2/n1), light can only be limited to propagate in the first phase A, so it is quickly emitted from the light-emitting layer 3 to enter other functional layers, and finally emitted from the quantum dot light-emitting device. As shown in FIG. 3, where FIG. 3 is a partial cross-sectional view of the light-emitting layer 3. Therefore, the light-emitting layer 3 having the two-phase structure according to the present disclosure can confine most of the light emitted from the quantum dot material 31 of the light-emitting layer 3 in the first phase A where the quantum dot material 31 is aggregated, making it tend to emit in a direction perpendicular to a plane of a film layer of the light-emitting layer (indicated by arrows), light loss caused by the waveguide mode in the light-emitting layer 3 is reduced, the light extraction efficiency of the QLED device is improved, and the external quantum efficiency of light emission of the QLED device is finally improved.

Preferably, a refractive index of the first polymer is greater than a refractive index of the second polymer.

It should be noted that both the first polymer and the second polymer belong to high molecular materials, and in general, a refractive index of the light-emitting layer is about 1.8, while a refractive index of common polymers is less than 1.8. Therefore, the refractive index of the first phase in which the quantum dot material is aggregated is generally higher than the refractive index of the second phase in which the quantum dot material is not contained. When light emitted from the quantum dot material passes through the interface between the first phase and the second phase, this means that light passes from an optically denser medium to an optically rarer medium.

It should be noted that a small amount of quantum dot material may also be present in the second phases due to a manufacturing process or the like, but it should be understood by those skilled in the art that the amount of the quantum dot material in the first phases is significantly higher than that in the second phases.

In particular, a size of the first phase is similar to a film thickness of the light-emitting layer, typically 10-30 nm.

It should be noted that a principle that an electroluminescent device emits light is as follows: holes from an anode and electrons from a cathode are transported to a light-emitting layer to be recombinated so as to emit light, due to the difference in energy level barriers between the anode and the light-emitting layer as well as between the cathode and the light-emitting layer, transport of electrons and holes is difficult, and the transport rates and quantities are also very different. In order to balance the concentration of electrons and holes, a hole injection layer and a hole transport layer are generally arranged between the light-emitting layer and the anode, and an electron injection layer and an electron transport layer are generally arranged between the light-emitting layer and the cathode. Of course, in specific implementation, it is possible to select which layers are needed according to actual needs. Optionally, as shown in FIG. 1, the quantum dot light-emitting device further includes a hole injection layer 6 between the anode and the hole transport layer 4, and an electron injection layer 7 between the cathode 2 and the electron transport layer 5.

Currently, an electroluminescent device can be divided into an electroluminescent device of a conventional structure and an electroluminescent device of an inverted structure, which differ in the order in which film layers are manufactured. Specifically, for the conventional structure, an anode, a hole injection layer, a hole transport layer, a light-emitting layer, an electron transport layer, an electron injection layer and a cathode are sequentially formed on a substrate; and for the inverted structure, a cathode, an electron injection layer, an electron transport layer, a light-emitting layer, a hole transport layer, a hole injection layer and an anode are sequentially formed on a substrate.

The quantum dot light-emitting device provided by the embodiment of the present disclosure may be of a conventional structure or an inverted structure, which is not limited.

In the present disclosure, there are no restrictions on the light-emitting type of the quantum dot light-emitting device, for example, being not limited to bottom light emission or top light emission. In specific implementation, the electrode, in the anode and the cathode, that is on a light-emitting side of the quantum dot light-emitting device is a transparent electrode.

In a general QLED device structure, a refractive index of a light-emitting layer containing a quantum dot material is different from those of other functional layers, and the refractive index of the light-emitting layer is generally maximum in order to dispersively emit light, but this also prevents light reflected by a reflection electrode on a non-light-emitting side from re-entering the light-emitting layer, and this part of the reflected light is lost, causing waste in the device. Therefore, in specific implementation, in the above quantum dot light-emitting device provided by embodiments of the present disclosure, as shown in FIG. 4, taking the condition that the quantum dot light-emitting device is of a conventional top emission structure as an example, the anode 1 is manufactured on a base substrate 10, the anode 1 is a reflection electrode, a refractive index n3 of the hole transport layer 4 and a refractive index n4 of the electron transport layer 5 are both approximately the same as the refractive index n2 of the second phase B. When the present disclosure takes a thin film containing the quantum dot material 31 and having a structure of phase separation as the light-emitting layer 3 of the QLED device, the refractive index n2 of the second phase B is designed to be approximately the same as the refractive index n3 of the hole transport layer 4 and the refractive index n4 of the electron transport layer 5 (i.e., n1>n2≈n3≈n4) so that most of light emitted by the quantum dot material 31 in the first phase A and reflected by the reflective anode 1 passes through the second phase B, and is then emitted from the top of the device, thus further improve the light extraction effect of the QLED device structure.

It should be noted that the refractive index n2 of the second phase B is approximately the same as the refractive index n3 of the hole transport layer 4 and the refractive index n4 of the electron transport layer 5, which means that a difference between the refractive index n2 of the second phase B and the refractive index n3 of the hole transport layer 4 is less than 0.3, and a difference between the refractive index n2 of the second phase B and the refractive index n4 of the electron transport layer 5 is less than 0.3.

It should be noted that FIG. 4 takes the condition that the quantum dot light-emitting device is of the conventional top emission structure as an example; of course, the quantum dot light-emitting device is also of an inverted top emission structure, i.e., a cathode is first manufactured on a substrate, and the cathode is a reflection electrode; the quantum dot light-emitting device is also of a conventional bottom emission structure, i.e., an anode is first manufactured on a substrate, and a cathode is a reflection electrode; the quantum dot light-emitting device is also of an inverted bottom emission structure, i.e., a cathode is first manufactured on a substrate, and an anode is a reflection electrode; and the selection is made according to actual needs.

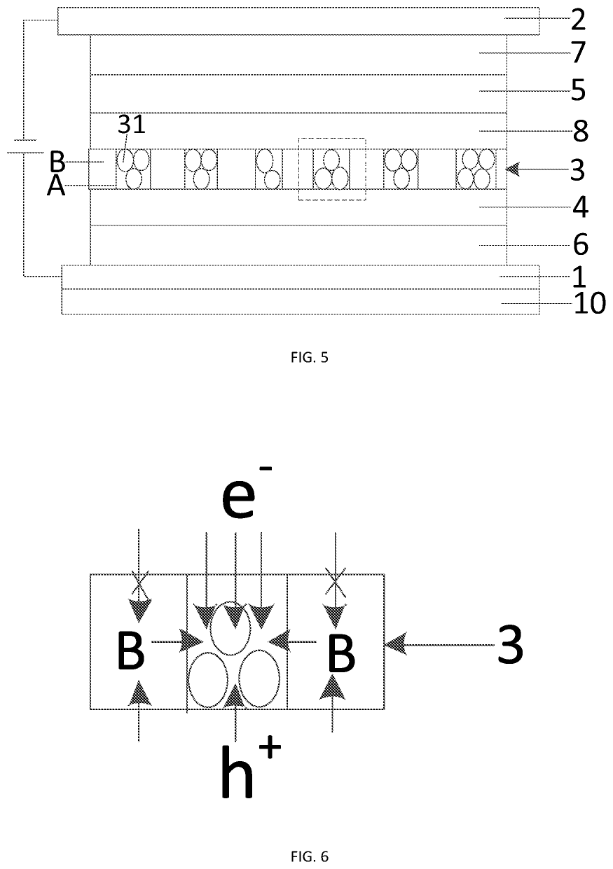

The principle that the electroluminescent device emits light is that: holes from the anode and electrons from the cathode are transported to the light-emitting layer to be recombinated to emit light, due to the difference in energy level barriers between the anode and the light-emitting layer as well as between the cathode and the light-emitting layer, transport of electrons and holes is difficult, and the transport rates and quantities are also very different. In order to balance the concentration of electrons and holes, a hole injection layer and a hole transport layer are generally arranged between the light-emitting layer and the anode, and an electron injection layer and an electron transport layer are generally arranged between the light-emitting layer and the cathode, but the quantum dot light-emitting device is also prone to the problem of unbalanced injection of electrons and holes. In specific implementation, in the above quantum dot light-emitting device provided by the embodiment of the present disclosure, as shown in FIG. 5, taking the condition that the quantum dot light-emitting device is of a conventional top emission structure as an example, the anode 1 is disposed on the base substrate 10, when the number of electrons reaching the light-emitting layer 3 per unit time is greater than the number of holes reaching the light-emitting layer 3 per unit time, and a ratio of the number of electrons reaching the light-emitting layer 3 per unit time to the number of holes reaching the light-emitting layer 3 per unit time is not within a first preset range, a material of the second polymer (a material of the second phase B) is set to be the same as a material of the hole transport layer 4, or a material of the second polymer is a hole transport material (a valence band is located between a valence band of the light-emitting layer and a valence band of the hole transport layer 4), or the second polymer is doped with a material that facilitates hole transport (high molecular or small molecular organic materials can be doped) so that the ratio of the number of electrons reaching the light-emitting layer 3 per unit time to the number of holes reaching the light-emitting layer 3 per unit time is within the first preset range to achieve the desired luminous efficiency; and the first preset range may be set as a range in which the quantum dot light-emitting device reaches the preset luminous efficiency.

Since direct contact between an electron transport material and a hole transport material may cause electric leakage, as shown in FIG. 5, the quantum dot light-emitting device further includes an electron blocking layer 8 between the light-emitting layer 3 and the electron transport layer 5. In this way, the carrier balance in the device can be adjusted, and electric leakage caused by direct contact between the electron transport layer 5 and the second polymer can be avoided, thereby increasing the internal quantum efficiency of the device.

As shown in FIG. 6, FIG. 6 is an enlarged schematic view of the structure in a dashed box shown in FIG. 5, on one hand, the electron blocking layer 8 can block a part of electrons e from being injected to the light-emitting layer 3 (arrows with x) to prevent electric leakage; on the other hand, the second polymer (having hole transport properties) and the hole transport layer 4 are in close contact with the quantum dot material 31, making injection of holes more efficient (arrows pointing upward and arrows pointing leftward and rightward), making injection of electrons and holes more balanced, and increasing the efficiency and service life of the device.

In specific implementation, in the above quantum dot light-emitting device provided by the embodiment of the present disclosure, the material of the second polymer includes, but is not limited to, poly(9,9-dioctylfluorene-co-N-(4-butylphenyl)diphenylamine), poly[N,N′-bis(4-butylphenyl)-N,N′-bis(phenyl)-benzi], polyphenylene vinylene or poly(9-vinylcarbazole), and a doping material in the second polymer includes, but is not limited to, 4,4′-bis(N-carbazole)-1,1′-biphenyl. Specifically: poly(9,9-dioctylfluorene-co-N-(4-butylphenyl)diphenylamine) is abbreviated as TFB; poly[N,N′-bis(4-butylphenyl)-N,N′-bis(phenyl)-benzi] is abbreviated as Poly-TPD; poly(9-vinylcarbazole) is abbreviated as PVK; polyphenylene vinylene is abbreviated as PPV; and 4,4′-bis(N-carbazolyl)-1,1′-biphenyl is abbreviated as CBP.

In specific implementation, in the above quantum dot light-emitting device provided by the embodiment of the present disclosure, a material of the electron blocking layer includes, but is not limited to, polyethylene, polypropylene, polytetrafluoroethylene, polycarbonate, polyamide, polymethyl methacrylate, alumina and silica. It will be understood by those skilled in the art that the selection of the material of the electron blocking layer can be made as long as it is possible to block the injection of at least a part of electrons from the electron transport layer 5 to the light-emitting layer 3.

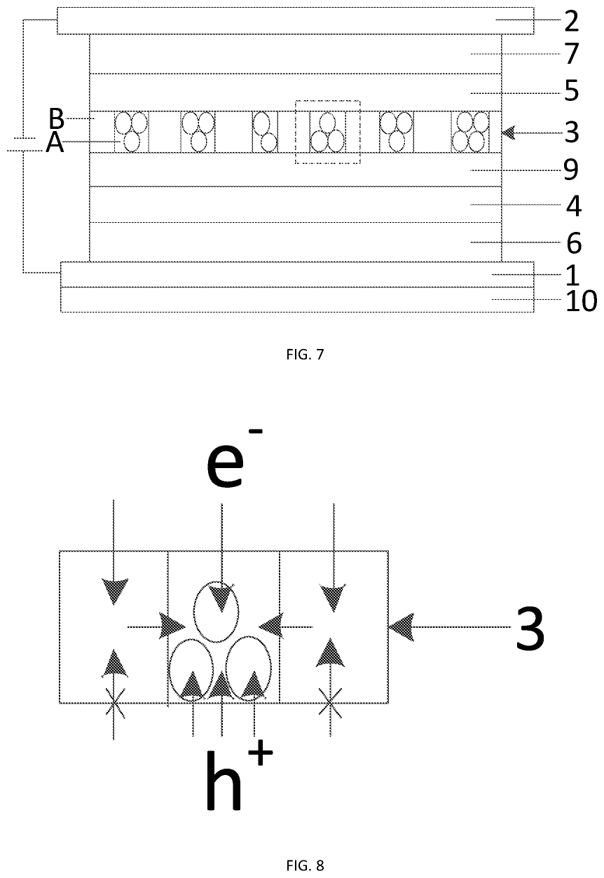

In specific implementation, in the above quantum dot light-emitting device provided by the embodiment of the present disclosure, as shown in FIG. 7, taking the condition that the quantum dot light-emitting device is of a conventional top emission structure as an example, the anode 1 is disposed on the base substrate 10, when the number of holes reaching the light-emitting layer 3 per unit time is greater than the number of electrons reaching the light-emitting layer 3 per unit time, and a ratio of the number of holes reaching the light-emitting layer 3 per unit time to the number of electrons reaching the light-emitting layer 3 per unit time are not in a second preset range, the material of the second polymer (the material of the second phase B) is the same as the material of the electron transport layer 5, or the material of the second polymer is an electron transport material (a valence band is located between the valence band of the light-emitting layer and a valence band of the electron transport layer 5), or the second polymer is doped with a material that facilitates electron transport (high molecular or small molecular organic materials can be doped) so that the ratio of the number of holes reaching the light-emitting layer 3 per unit time to the number of electrons reaching the light-emitting layer 3 per unit time is within the second preset range to achieve the desired luminous efficiency; and the second preset range may be set as a range in which the quantum dot light-emitting device reaches the preset luminous efficiency.

Since direct contact between the electron transport material and the hole transport material may cause electric leakage, as shown in FIG. 7, the quantum dot light-emitting device further includes a hole blocking layer 9 between the light-emitting layer 3 and the hole transport layer 4. In this way, the carrier balance in the device can be adjusted, and electric leakage caused by direct contact between the hole transport layer 4 and the second polymer can be avoided, thereby increasing the internal quantum efficiency of the device.

As shown in FIG. 8, FIG. 8 is an enlarged schematic view within a dashed box of FIG. 7, on one hand, the hole blocking layer 9 may block a part of holes h⁺ from being injected to the light-emitting layer 3 (arrows with x) to prevent electric leakage, on the other hand, the second polymer (a material facilitating electron transport) and the electron transport layer 5 are in close contact with the quantum dot material 31, making injection of electrons more efficient (arrows pointing downward and arrows pointing leftward and rightward), making injection of electrons and holes more balanced, and increasing the efficiency and service life of the device.

In specific implementation, in the above quantum dot light-emitting device provided by the embodiment of the present disclosure, the doping material in the second polymer includes, but is not limited to, 4,7-diphenyl-1,10-phenanthroline, 1,3,5-tris(1-phenyl-1H-benzimidazol-2-yl)benzene, 2,8-bis(diphenylphosphoryl)dibenzofuran, and 1,3,5-tris[(3-pyridyl)-3-phenyl]benzene. Specifically, 4,7-diphenyl-1,10-phenanthroline is abbreviated as BPhen; 1,3,5-tris(1-phenyl-1H-benzimidazol-2-yl)benzene is abbreviated as TPBi; 2,8-bis(diphenylphosphoryl)dibenzofuran is abbreviated as PPF; and 1,3,5-tris[(3-pyridyl)-3-phenyl]benzene is abbreviated as TmPyBP.

In specific implementation, in the above quantum dot light-emitting device provided by the embodiment of the present disclosure, a material of the hole blocking layer includes, but is not limited to, polyethylene, polypropylene, polytetrafluoroethylene, polycarbonate, polyamide, polymethyl methacrylate, alumina or silica. It will be understood by those skilled in the art that the selection of the material of the hole blocking layer can be made as long as it is possible to block the injection of at least a part of holes from the hole transport layer 4 to the light-emitting layer 3.

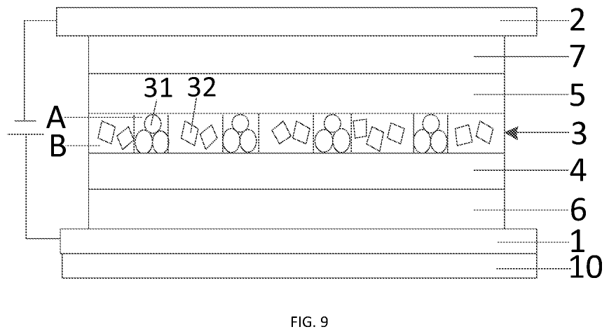

In specific implementation, in order to further enhance the luminous efficiency of the quantum dot light-emitting device, in the above quantum dot light-emitting device provided by the embodiment of the present disclosure, as shown in FIG. 9, taking the condition that the quantum dot light-emitting device is of a conventional top emission structure as an example, the anode 1 is disposed on the base substrate 10, the second phase B further includes nanoparticles 32, and the nanoparticles 32 are configured to generate localized surface plasmon resonance when is irradiated by light of a preset wavelength, to enhance a local electric field. Specifically, dispersing the nanoparticles 32 within the second phase B of the light-emitting layer 3 can avoid direct contact of the nanoparticles 32 with the quantum dot material 31 in the first phase A, avoiding exciton quenching. And when the nanoparticles 32 are irradiated with light of a suitable wavelength, the local electric field can be enhanced by the localized surface plasmon resonance effect of the nanoparticles 32, thereby enhancing the light emission of the quantum dot material 31, and further enhancing the luminous efficiency of the QLED device.

In specific implementation, in the above quantum dot light-emitting device provided by the embodiment of the present disclosure, the nanoparticles are metallic nanoparticles, in order to achieve full color display, the light-emitting layer has a plurality of sub-pixels with different light-emitting colors, and each sub-pixel includes quantum dot materials of the same color. Since the sizes of quantum dot materials of different colors are different, in order to match with the sizes of the quantum dot materials to effectively improve the luminous efficiency of the QLED device, the same metal nanoparticles corresponding to the quantum dot materials of different colors have different sizes.

In specific implementation, in the above quantum dot light-emitting device provided by the embodiment of the present disclosure, the light-emitting layer may include a first sub-pixel emitting red light, a second sub-pixel emitting green light, and a third sub-pixel emitting blue light, the first sub-pixel includes a red quantum dot material, the second sub-pixel includes a green quantum dot material, the third sub-pixel includes a blue quantum dot material. The particle size of the metal nanoparticles to which the red quantum dot material corresponds, the particle size of the metal nanoparticles to which the green quantum dot material corresponds, and the particle size of the metal nanoparticles to which the blue quantum dot material corresponds decrease sequentially, so as to effectively improve the luminous efficiency of the QLED device.

In specific implementation, in the above quantum dot light-emitting device provided by the embodiment of the present disclosure, a material of the nanoparticles includes, but is not limited to, at least one of Ag, Au, Pt, Pd, Cu or Al.

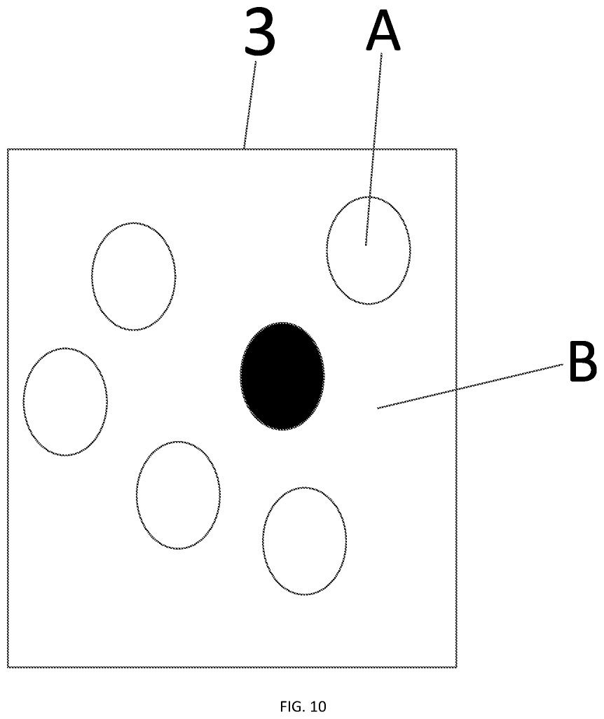

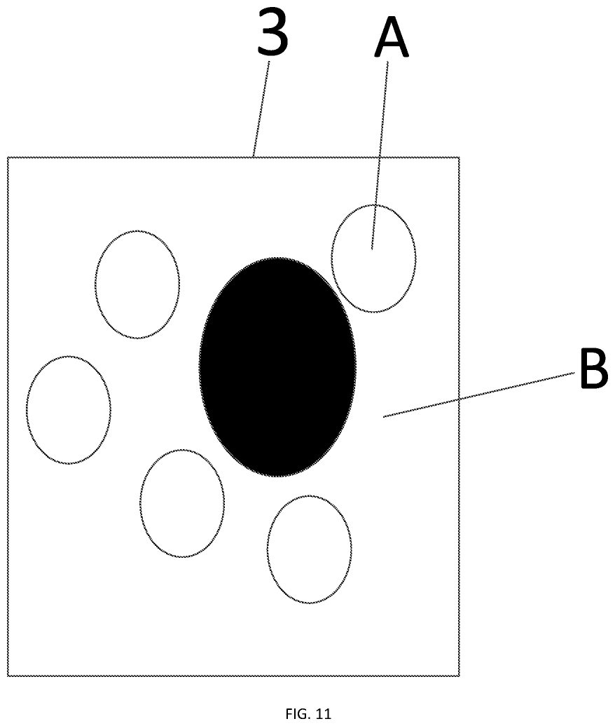

In the QLED device, when there are some weak points in the light-emitting layer, excessive local current will be caused, heat generation is pronounced, and under the combined action of electricity and heat, the light-emitting layer is degraded and destroyed, and dark spots are formed and gradually diffused. In order to prevent the diffusion of dark spots formed by degradation and destruction of the light-emitting layer, in the above quantum dot light-emitting device provided by the embodiment of the present disclosure, as shown in FIG. 1, FIG. 4, FIG. 5, FIG. 7 and FIG. 9, the material of the second polymer (the material of the second phase B) includes a crosslinked polymeric material or a polymeric material with a melting point greater than a preset value. Specifically, the polymeric material with the melting point greater than the preset value refers to a polymeric material with a melting point greater than 100° C., so that when subject to thermal degradation, the higher melting point of the material of the second phase B prevents it from melting easily; and when subject to the chemical degradation, the material of the second phase B employs the crosslinked polymeric material, which is not easily be subjected to a chemical reaction. Thus, by designing the light-emitting layer 3 to be of a structure having the first phase A (which is a dispersed phases) and the second phase B (which is a continuous phase), and designing the material of the second polymer in the second phase B to be a chemically stable material (e.g., a crosslinked polymeric material or a high-melting-point material), local degradation of the first phase A of the light-emitting layer 3 can be limited to an independent region of the first phases A, avoiding diffusion after formation of dark spots. As shown in FIGS. 10 and 11, FIG. 11 shows a schematic diagram of the continued diffusion of dark dots formed by degradation and destruction of the light-emitting layer when the material of the second polymer in the second phase B does not adopt a chemically stable material, FIG. 10 shows a schematic diagram of no diffusion of dark dots formed by degradation and destruction of the light-emitting layer when the material of the second polymer in the second phase B adopts a chemically stable material according to an embodiment of the present disclosure, so the light-emitting layer of a phase separation structure according to the present disclosure can improve the stability and reliability of the QLED device.

It should be noted that the features of the above embodiments provided by the embodiments of the present disclosure may be combined with each other.

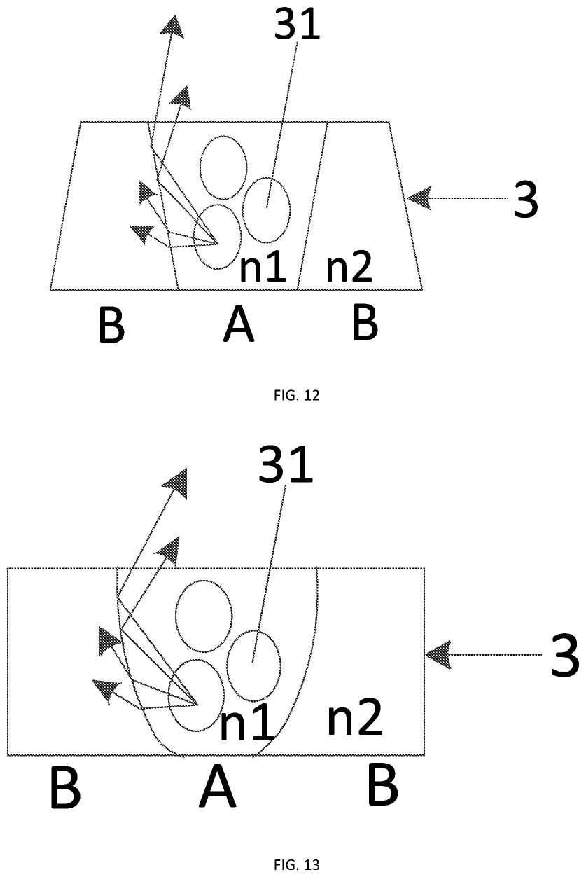

In specific implementation, in the above quantum dot light-emitting device provided by the embodiment of the present disclosure, as shown in FIG. 1, FIG. 3, FIG. 4, FIG. 5, FIG. 7 and FIG. 9, along a direction perpendicular to the cathode 2, a cross-sectional shape of the first phase A is square; of course, the cross-sectional shape of each of the first phase A may also be an inverted trapezoid, as shown in FIG. 12; the cross-sectional shape of the first phase A may also be a curved surface shape, as shown in FIG. 13; and the cross-sectional shapes in FIGS. 12 and 13 are more conducive to light emission. Of course, the cross-sectional shapes of the first phases A with consistent design ideas are within the protection scope of the present disclosure.

It should be noted that a cross section of the first phase A in the direction perpendicular to the cathode 2 means that the cathode 2 is disposed generally parallel to the base substrate, and the base substrate is viewed as a horizontal plane, and the cross section of the first phase A is obtained by cutting from a vertical direction perpendicular to the horizontal plane.

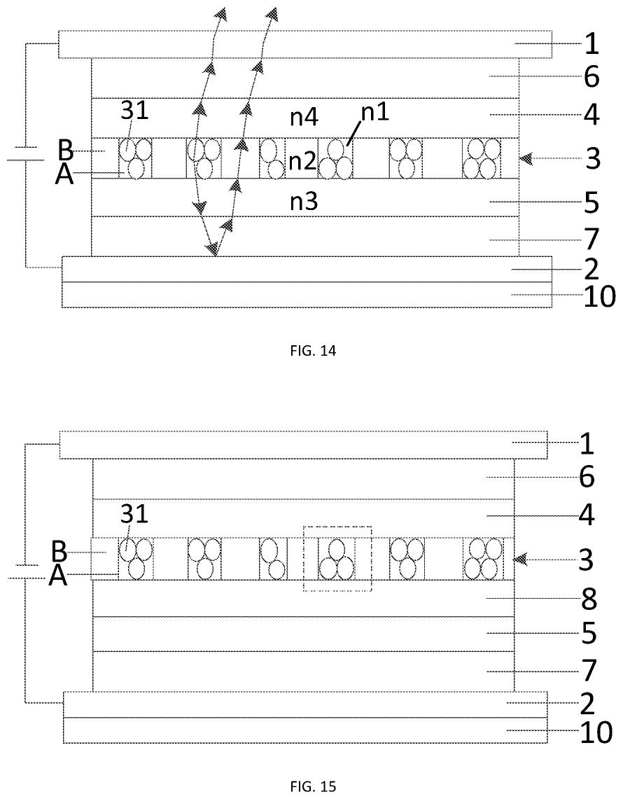

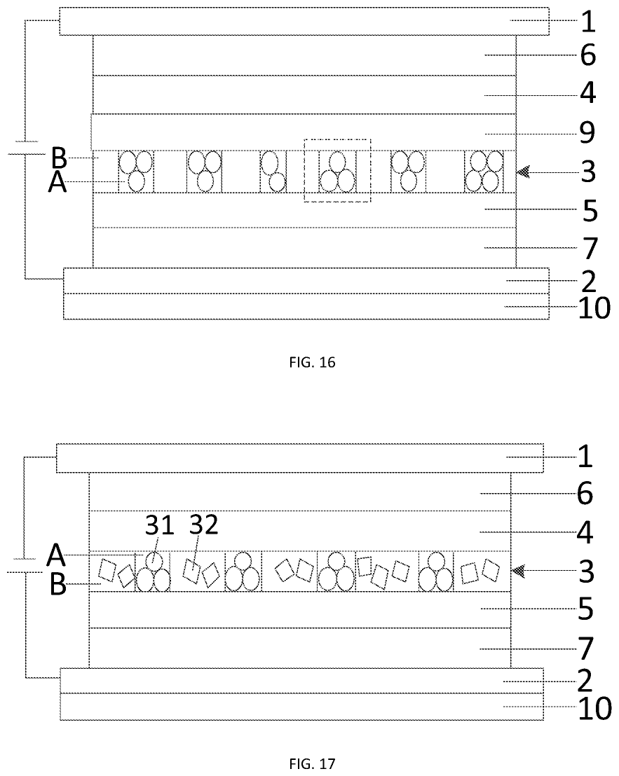

It should be noted that the quantum dot light-emitting devices shown in FIG. 4, FIG. 5, FIG. 7 and FIG. 9 are all illustrated by taking the conventional top emission structure as an example, and of course, the quantum dot light-emitting device may also be of an inverted top emission structure, as shown in FIG. 14, FIG. 15, FIG. 16 and FIG. 17, respectively, and a difference is that a manufacturing order of film layers is different. Of course, a conventional bottom emission structure or an inverted bottom emission structure is also possible, which is not listed here.

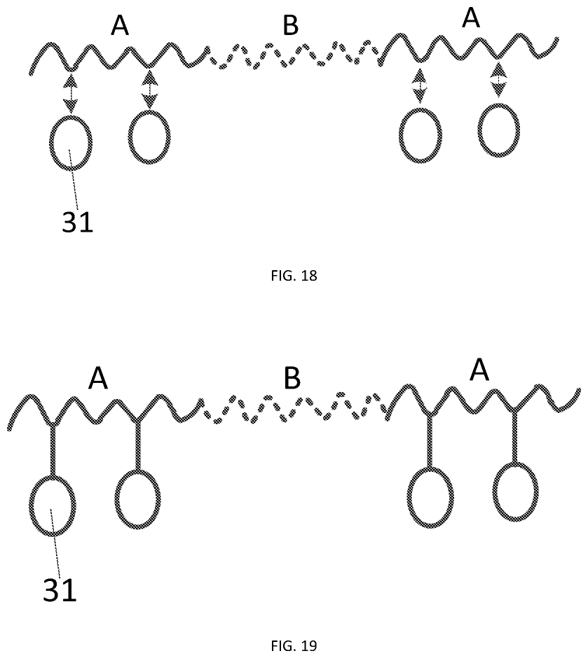

In specific implementation, since it is desirable that the quantum dot material is aggregated within the first phase, and it is desirable that there is no aggregated quantum dot material within the second phase in the embodiments of the present disclosure, it is necessary to design the quantum dot material, the material of the first polymer and the material of the second polymer in such a way that the quantum dot material is more easily aggregated in the first phases. Therefore, in the above quantum dot light-emitting device provided by the embodiment of the present disclosure, as shown in FIG. 18, the quantum dot material 31 can be hydrophobic, the first polymer (the material of the first phase A, indicated by a solid wavy line) is a hydrophobic material, and the second polymer (the material of the second phase B, indicated by a dashed wavy line) is a hydrophilic material. Based on the hydrophilicity and hydrophobicity, an interaction of the hydrophobic quantum dot material 31 with the hydrophobic first phase A is stronger than an interaction of the hydrophobic quantum dot material 31 with the hydrophilic second phase B, and thus the quantum dot material 31 tends to bond to the first polymer of the first phase A (indicated by bidirectional arrows), thus forming the light-emitting layer having the phase separation structure.

In specific implementation, in the above quantum dot light-emitting device provided by the embodiment of the present disclosure, as shown in FIG. 18, the quantum dot material 31 has a hydrophobic ligand, the hydrophobic ligand may include a coordination group that coordinates with the quantum dots, and an alkane group connected with the coordination group. The hydrophilicity and hydrophobicity of the quantum dot material generally depend on the ligand, since the alkane group is generally hydrophobic, the quantum dot material 31 is hydrophobic. The hydrophobic first polymer (the material of the first phase A) includes, but is not limited to, polystyrene, and the hydrophilic second polymer (the material of the second phase B) includes, but is not limited to, polyethylene oxide, polymethyl methacrylate, polyacrylate or polyamide.

In specific implementation, in the above quantum dot light-emitting device provided by the embodiment of the present disclosure, as shown in FIG. 18, the quantum dot material 31 may also be a hydrophilic material, the first polymer (the material of the first phase A, indicated by a solid wavy line) is a hydrophilic material, and the second polymer (the material of the second phase B, indicated by a dashed wavy line) is a hydrophobic material. Based on the hydrophilicity and hydrophobicity, an interaction of the hydrophilic quantum dot material 31 with the hydrophilic first phases A is stronger than an interaction of the hydrophilic quantum dot material 31 with the hydrophobic second phases B, and thus the hydrophilic quantum dot material 31 tends to bond to the first polymer of the hydrophilic first phase A (indicated by bidirectional arrows), thereby forming the light-emitting layer having the phase separation structure.

In specific implementation, in the above quantum dot light-emitting device provided by the embodiment of the present disclosure, as shown in FIG. 18, the quantum dot material 31 has a hydrophilic ligand, where the hydrophilic ligand includes a coordination group that coordinates with the quantum dots, an alkane group connected with the coordination group, and a hydrophilic group connected with the alkane group, where the hydrophilic group includes, but is not limited to, hydroxy, amino, mercapto, carboxyl or a sulfonic acid group.

Since the hydroxy, the amino, the mercapto, the carboxyl, or the sulfonic acid group is generally hydrophilic, the ligand of the quantum dot material 31 is hydrophilic, and thus the quantum dot material 31 is also hydrophilic. The hydrophilic first polymer (the material of the first phase A) includes, but is not limited to, polyethylene oxide, polymethyl methacrylate, polyacrylate or polyamide, and the hydrophobic second polymer (the material of the second phase B) includes, but is not limited to, polyolefin or polystyrene.

In specific implementation, in the above quantum dot light-emitting device provided by the embodiment of the present disclosure, as shown in FIG. 19, in the first phase A, the quantum dot material 31 is bonded to at least part of the first polymer (the material of the first phase A) through coordination bonds.

The second polymer (the material of the second phase B) and the quantum dot material 31 cannot be subjected to coordination binding. Thus, the quantum dot material 31 tends to be subjected to coordination binding with the first polymer of the first phase A, thus forming the light-emitting layer having the phase separation structure.

In specific implementation, in the above quantum dot light-emitting device provided by the embodiment of the present disclosure, as shown in FIG. 19, the first polymer (the material of the first phase A) includes, but is not limited to, a side chain having hydroxy, carboxyl, amino or mercapto. Here, the hydroxy, the carboxyl, the amino or the mercapto or the like can be subjected to coordination binding with the quantum dot material 31. In this case, the first polymer acts as a ligand of the quantum dot material 31. Of course, it is also possible that the first polymer is directly connected to a ligand of the quantum dot material 31 itself.

In specific implementation, the quantum dot light-emitting device provided by the embodiment of the present disclosure also includes other functional film layers well known to those skilled in the art, which is not described in detail here.

Optionally, in the above quantum dot light-emitting device provided by the embodiment of the present disclosure, the quantum dot material may include, but is not limited to, quantum dots such as CdS, CdSe, ZnSe, InP, PbS, CsPbCl₃, CsPbBr₃, CsPhI₃, CdS/ZnS, CdSe/ZnS, CdSe/ZnSe, InP/ZnS, PbS/ZnS, CsPbCl₃/ZnS, CsPbBr₃/ZnS, CsPhI₃/ZnS, and ZnTeSe/ZnSe.

Further, in specific implementation, in the above quantum dot light-emitting device provided by the embodiment of the present disclosure, when the electron transport material is selected from organic materials, the electron transport material includes, but is not limited to, Bphen and the like; and when the electron transport material is selected from inorganic materials, the electron transport material includes, but is not limited to, one or a combination of ZnO, TiO₂, ZrO₂, SnO₂, Nb₂O₅, In₂O₃, and ZnMgO.

Further, in specific implementation, in the above quantum dot light-emitting device provided by the embodiment of the present disclosure, when the hole transport material is selected from organic materials, the hole transport material includes, but is not limited to, one or a combination of TFB, Poly-TPD, CBP, PPV, and PVK; and when the hole transport material is selected from inorganic materials, the hole transport material includes, but is not limited to, one or a combination of NiOx, WOx, MoOx, VOx, and CrOx.

Further, in specific implementation, in the above quantum dot light-emitting device provided by the embodiment of the present disclosure, a material of the hole injection layer may include, but is not limited to, one or a combination of PEDOT:PSS, CuPc, a transition metal oxide, and a metal chalcogenide. Where the transition metal oxide includes, but is not limited to, one or a combination of MoOx, VOx, WOx, CrOx, and CuO, and the metal chalcogenide includes, but is not limited to, one or a combination of MoS₂, MoSe₂, WS₂, WSe₂, and CuS.

Further, in specific implementation, in the above quantum dot light-emitting device provided by the embodiment of the present disclosure, the anode may be made of a metal material such as aluminum and silver, or may be made of a doped metal oxide including but not limited to one or more of indium-doped tin oxide (ITO), indium-doped zinc oxide (IZO), and the like.

Further, in specific implementation, in the above quantum dot light-emitting device provided by the embodiment of the present disclosure, the cathode may be made of one or more of a metal material, a conductive metal oxide material, and a conductive carbon material. The metal material includes, but is not limited to, one or more of Al, Ag, Cu, Mo, Au, or alloys thereof; the conductive metal oxide material includes, but is not limited to, one or more of ITO, IZO, and AZO; and the conductive carbon material include, but is not limited to, one or more of carbon nanotubes, graphene, graphene oxide, and the like.

Based on the same inventive concept, an embodiment of the present disclosure further provides a manufacturing method for the above quantum dot light-emitting device, including: forming an anode and a cathode which are disposed in opposite, forming a light-emitting layer between the anode and the cathode, forming a hole transport layer between the anode and the light-emitting layer, and forming an electron transport layer between the cathode and the light-emitting layer.

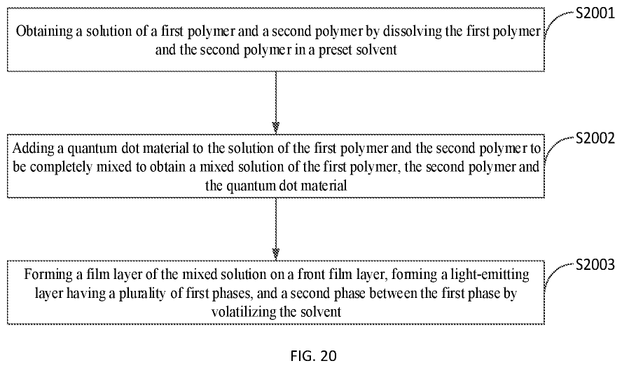

As shown in FIG. 20, forming the light-emitting layer may specifically include the following steps.
S2001, obtaining a solution of a first polymer and a second polymer by dissolving the first polymer and the second polymer in a preset solvent.
S2002, adding a quantum dot material to the solution of the first polymer and the second polymer to be completely mixed to obtain a mixed solution of the first polymer, the second polymer and the quantum dot material.
S2003, forming a film layer of the mixed solution on a front film layer, forming a light-emitting layer having a plurality of first phases, and a second phase between the first phase by volatilizing the solvent.

Specifically, the film layer of the mixed solution may be formed on the front film layer by a spin coating method, and volatilizing the solvent may be implemented as natural volatilizing and heating drying; and the film layer of the mixed solution may also be formed on the front film layer by inkjet printing or electrospray printing, and volatilizing the solvent may be implemented as vacuum drying and heating drying.

According to the manufacturing method for the above quantum dot light-emitting device provided by the embodiment of the present disclosure, when the light-emitting layer is manufactured, by controlling the drying conditions of film-forming, microphase separation of island-like having a size of tens of nanometers occurs during the drying film-forming process, the quantum dot material can be automatically aggregated in the phases where the first polymer is located, the light-emitting layer having a two-phase structure of a plurality of first phases, and a second phase between the first phases is formed, the manufacturing method is simple, and the synthesis is easy.

A manufacturing method for the quantum dot light-emitting device of the conventional structure provided by the embodiment of the present disclosure will be described in detail below by specific embodiments. Specifically, manufacturing methods of film layers in the quantum dot light-emitting device include, but are not limited to, one or more of a spin coating method, an evaporation method, a chemical vapor deposition method, a physical vapor deposition method, a magnetron sputtering method, and the like.

### Embodiment 1: The Steps of Manufacturing a Device Structure Shown in FIG. 1 (Taking a Conventional Structure as an Example) are as Follows

(1) A patterned anode 1 is formed on a glass base substrate, where a material of the anode 1 may include a metal material such as aluminum and/or silver.

(2) A hole injection layer 6 is formed by spin coating, where a material of the hole injection layer 6 is, for example, PEDOT:PSS.

(3) A hole transport layer 4 is formed by spin coating, evaporation, sputtering or inkjet printing, where a material of the hole transport layer 4 may be an organic material such as TFB, TPD, Poly-TPD, CBP, PPV, PVK or the like, or a material of the hole transport layer may be an inorganic HT material such as NiO, WO₃ or the like.

(4) A light-emitting layer 3 is formed by spin coating or inkjet printing, where the drying conditions for film-forming are controlled, the light-emitting layer 3 having a two-phase structure of a plurality of first phases A, and a second phase B between the first phases A is formed, and a quantum dot material 31 is aggregated in the first phases A. Specifically, polystyrene-b-poly(2-vinylpyridine) (PS-b-P2VP) is mixed with tri-n-octylphosphine oxide (TOPO)-coated cadmium selenide (CdSe) quantum dots, and a solvent is toluene; and the first phase is P2VP, the second phase is PS, and the quantum dot material is aggregated in the first phases P2VP.

(5) An electron transport layer 5 is formed by spin coating, evaporation or sputtering, where a material of the electron transport layer 5 may include an organic material such as BPhen; or a material of the electron transport layer 5 may include an inorganic material such as ZnO nanoparticles and ZnMgO nanoparticles.

(6) An electron injection layer 7 is formed by spin coating, evaporation or sputtering, where a material of the electron injection layer 7 is the same as that in the related art.

(7) A cathode 2 is formed by evaporation or sputtering, where a material of the cathode 2 may include transparent conductive glass ITO, IZO or the like.

### Embodiment 2: The Steps of Manufacturing a Device Structure Shown in FIG. 4 are as Follows

A manufacturing method of the device structure shown in FIG. 4 is the same as that of the device structure shown in FIG. 1, the light-emitting layer includes a first phase P2VP, and a second phase PS; a difference between manufacturing methods of the structures shown in FIG. 4 and FIG. 1 is that: a refractive index of the selected second polymer PS is approximately the same as a refractive index of the electron transport layer (ZnO) and a refractive index of the hole transport layer (TFB). For example, TFB has a refractive index of 1.7-1.85, ZnO has a refractive index of about 1.9, PS has a refractive index of about 1.6, and PS belongs to a polymer material with a high refractive index, and has an effect of enhancing emission of reflected light compared with general polymer materials.

### Embodiment 3: The Steps of Manufacturing a Device Structure Shown in FIG. 5 are as Follows

A manufacturing method of the device structure shown in FIG. 5 is similar to that of the device structure shown in FIG. 1, and a difference between methods of manufacturing the structures shown in FIG. 5 and FIG. 1 is that: the light-emitting layer 3 includes a first phase poly(2-vinylpyridine) (P2VP) and second phase polyvinylcarbazole (PVK). Polyvinylcarbazole (PVK) is a material that facilitates hole transport, and accordingly an electron blocking layer 8 is required between the light-emitting layer 3 and the electron transport layer 5. In addition, the hole transport layer is made of a crosslinked material to prevent subsequent dissolution by a solvent.

### Embodiment 4: The Steps of Manufacturing a Device Structure Shown in FIG. 9 are as Follows

A manufacturing method of the device structure shown in FIG. 9 is similar to that of the device structure shown in FIG. 1, and a difference between manufacturing methods of the structures shown in FIG. 9 and FIG. 1 is that: the light-emitting layer 3 is formed by using a PS-b-P2VP block copolymer, finally forming a structure in which the quantum dot material is aggregated in the first phase P2VP and Au nanoparticles are dispersed in the second phase PS.

The manufacturing of the light-emitting layer is specifically as follows.

(1) The PS-b-P2VP block copolymer and a quantum dot material (e.g., a mass fraction of PS is 5%) are dissolved in a methanol solvent to prepare a 5 wt % mixed solution, and in this case, micelles in which the second phase is PS and the first phase is P2VP are formed, and the quantum dot material is dispersed in the first phases P2VP.

(2) An appropriate amount of a toluene solution containing 1 wt % of Au nanoparticles is added to the mixed solution to manufacture phase inversion micelles. Since PS is easily soluble in toluene and P2VP is not easily soluble, micelles with the quantum dot material and P2VP as the first phase, and PS as the second phases will be formed, and Au nanoparticles are dispersed in the second phase PS.

(3) The solvent is volatilized to form a thin film so that a structure in which the quantum dot material is in the first phases P2VP, and the Au nanoparticles are in the second phase PS can be obtained.

### Embodiment 5

A device has a structure shown in FIG. 1, and a light-emitting layer is formed by mixing polystyrene-b-poly(2-vinylpyridine) (PS-b-P2VP) mixed with a crosslinking agent divinylbenzene (DVB) with a tri-n-octylphosphine oxide (TOPO)-coated quantum dot material, and a solvent is toluene. After drying to form a film, a structure in which the first phase is P2VP and the second phase is PS is formed, and the quantum dot material is aggregated in the first phase P2VP. The film is then heated to remove the solvent by drying, and the material PS of the second phase is allowed to be crosslinked under the action of DVB, i.e., the second polymer uses a chemically stable material, preventing the problem of blackening and diffusion due to degradation of the quantum dot material in the first phases.

The manufacturing of the light-emitting layer is specifically as follows.

(1) A 5 wt % toluene solution is prepared by selecting PS-b-P2VP in which a molecular weight of PS is 55,000 and a molecular weight of P2VP is 18,000, and a suitable amount of a crosslinking agent DVB (e.g., PS with 5 wt % DVB).

(2) Tri-n-octylphosphine oxide (TOPO)-coated CdSe nanoparticles are prepared, where the diameter of the CdSe nanoparticles is 4 nm, and the CdSe nanoparticles are added to the above toluene solution of PS-b-P2VP, where the concentration of the CdSe nanoparticles is 1 wt %.

(3) The above prepared solution is spin-coated, naturally volatilized, and then dried by heating at 170° C. so that a two-phase structure in which a CdSe quantum dot material is aggregated in the first phases P2VP can be manufactured, where crosslinking occurs between chain segments in the second phase PS, and a film thickness is controlled to be in the range of 10-30 nm.

Encapsulation is performed after the manufacture of the film layers of the above quantum dot light-emitting device is finished, completing the manufacture of the quantum dot light-emitting device of the conventional structure in the embodiment of the present disclosure.

The quantum dot light-emitting device manufactured by the above method in the embodiment of the present disclosure is of the conventional structure, of course, in specific implementation, the quantum dot light-emitting device of the inverted structure can also be manufactured, specifically, the quantum dot light-emitting device of the inverted structure is that a cathode, an electron injection layer, an electron transport layer, a light-emitting layer, a hole transport layer, a hole injection layer and an anode are formed on a glass base substrate in sequence; and a specific manufacturing flow of the quantum dot light-emitting device of the inverted structure can refer to the above manufacturing method for the quantum dot light-emitting device of the conventional structure, and only the manufacturing order of the film layers is changed, which will not be described in detail here. In addition, top emission or bottom emission can be achieved by designing the materials of the cathode and the anode.

The above manufacturing method for the quantum dot light-emitting device does not make detailed description of a manufacturing method for the light-emitting layer, the manufacturing method for the light-emitting layer is described in detail by specific embodiments, and a main difference of the manufacturing method for the light-emitting layer in the following embodiments is that the materials of the first polymer and the second polymer are different.

### Embodiment I

In this embodiment, a quantum dot material is hydrophobic, a first polymer is a hydrophobic material, and a second polymer is a hydrophilic material is taken as an example.

A quantum dot light-emitting device structure is, for example, a conventional bottom emission structure, and a specific structure is anode (ITO)/hole injection layer (PEDOT:PSS)/hole transport layer (TFB)/light-emitting layer/electron transport layer (ZnO)/cathode (Al). Manufacturing methods of the anode, the hole injection layer, the hole transport layer, the electron transport layer and the cathode refer to the steps of the aforementioned manufacturing method for the quantum dot light-emitting device, which will not be described in detail here.

The quantum dot material is hydrophobic cadmium selenide (CdSe) quantum dots with oleic acid ligands, the first polymer is hydrophobic polystyrene (PS), and the second polymer is hydrophilic polyethylene oxide (PEO).

Manufacture of the light-emitting layer is: a polyethylene oxide-polystyrene block copolymer (PEO-b-PS) is mixed with a hydrophobic quantum dot material, and a solvent may be dimethylformamide (DMF). After drying to form a film, the formed first phase (PS) has a refractive index of 1.5894, the formed second phase (PEO) has a refractive index of 1.4539, and the quantum dot material is aggregated in the first phases (PS).

Detailed steps of manufacturing the light-emitting layer are as follows.

(1) 0.2 g of PEO-b-PS in which a molecular weight of PEO is 16000 and a molecular weight of PS is 39,000 is selected and dissolved in 10 ml of N-methyl-2-pyrrolidone (NMP) to prepare a PEO-b-PS solution having a concentration of 20 mg/mL.

(2) The PEO-b-PS solution is heated under stirring at 50° C. for 1 h to make the PEO-b-PS solution to be completely dissolved.

(3) 0.2 g of oil-soluble cadmium selenide (CdSe) quantum dots with oleic acid ligands is added to the above PEO-b-PS solution, and dissolved uniformly under stirring to prepare a mixed solution of PEO-b-PS and the quantum dot material.

(4) The above prepared mixed solution of PEO-b-PS and the quantum dot material is spin-coated, naturally volatilized, and then dried by heating so that a light-emitting layer having a plurality of first phases, and the second phase between the first phases is formed, where a film thickness of the light-emitting layer is controlled to be in the range of 10-30 nm.

### Embodiment II

In this embodiment, a quantum dot material is hydrophilic, a first polymer is a hydrophilic material, and a second polymer is a hydrophobic material is taken as an example.

A quantum dot light-emitting device structure is, for example, a conventional bottom emission structure, and a specific structure is anode (ITO)/hole injection layer (PEDOT:PSS)/hole transport layer (TFB)/light-emitting layer/electron transport layer (ZnO)/cathode (Al).

Manufacturing methods of the anode, the hole injection layer, the hole transport layer, the electron transport layer and the cathode refer to the steps of the aforementioned manufacturing method for the quantum dot light-emitting device, which will not be described in detail here.

The quantum dot material is tri-n-octylphosphine oxide (TOPO)-coated cadmium selenide (CdSe) quantum dots, the first polymer is poly(2-vinylpyridine), and the second polymer is polystyrene.

Manufacture of the light-emitting layer is: polystyrene-b-poly(2-vinylpyridine) (PS-b-P2VP) is mixed with tri-n-octylphosphine oxide (TOPO)-coated cadmium selenide (CdSe) quantum dots, and a solvent is toluene. After drying to form a film, the formed first phase is P2VP, the formed second phase is PS, and the quantum dot material is aggregated in the first phases P2VP.

Detailed steps of manufacturing the light-emitting layer are as follows.

(1) PS-b-P2VP in which a molecular weight of PS is 55,000 and a molecular weight of P2VP is 18,000 is selected to prepare a 5 wt % toluene solution.

(2) Tri-n-octylphosphine oxide (TOPO)-coated CdSe nanoparticles are prepared, where the diameter of the CdSe nanoparticles is 4 nm, and the CdSe nanoparticles are added to the above toluene solution of PS-b-P2VP to form a mixed solution, where the concentration of the CdSe nanoparticles is 1 wt %.

(3) The mixed solution prepared above is spin-coated, naturally volatilized, and then dried by heating at 170° C. so that a two-phase structure in which CdSe nanoparticles are aggregated in the first phases P2VP can be formed, where a film thickness of the light-emitting layer is controlled to be in the range of 10-30 nm.

### Embodiment III

In this embodiment, a quantum dot material is bonded to at least part of a first polymer through coordination bonds, and a second polymer and the quantum dot material are unable to be subjected to coordination binding is taken as an example.

A quantum dot light-emitting device structure is, for example, a conventional bottom emission structure, and a specific structure is anode (ITO)/hole injection layer (PEDOT:PSS)/hole transport layer (TFB)/light-emitting layer/electron transport layer (ZnO)/cathode (Al). Manufacturing methods of the anode, the hole injection layer, the hole transport layer, the electron transport layer and the cathode refer to the steps of the aforementioned manufacturing method for the quantum dot light-emitting device, which will not be described in detail here.

The quantum dot material is cadmium selenide (CdSe) quantum dots, the first polymer is polyacrylate (PAA), and the second polymer is polystyrene (PS).

Manufacture of the light-emitting layer: polyacrylate-b-polystyrene (PAA-b-PS) is mixed with cadmium selenide (CdSe) quantum dots, and a solvent is toluene. After drying to form a film, the formed first phase is PAA, the formed second phase is PS, and the quantum dot material is aggregated in the first phases PAA, and CdSe coordinates with carboxyl of a chain segment side chain of PAA.

Detailed steps of manufacturing the light-emitting layer are as follows.

(1) CdSe, PS, and PAA are selected, where a molecular weight of PS is 5000 and a molecular weight of PAA is also 5000, and CdSe, PS, and PAA are dissolved in tetrahydrofuran (THF) to prepare a 2 mg/ml mixed solution.

(2) The mixed solution prepared above is spin-coated, naturally volatilized, and then dried by heating at 170° C. so that a two-phase structure in which CdSe nanoparticles are aggregated in the first phases PAA can be manufactured, where a film thickness of the light-emitting layer is controlled to be in the range of 10-30 nm.

Based on the same inventive concept, an embodiment of the present disclosure further provides a display apparatus, including the above quantum dot light-emitting device provided by the embodiment of the present disclosure. The display apparatus may be any product or component having a display function, such as a mobile phone, a tablet computer, a television, a display, a notebook computer, a digital photo frame and a navigator. Other essential components of the display apparatus should be understood by those of ordinary skill in the art, and will not be repeated here, nor should they be regarded as a limitation to the present disclosure. The principle of solving the problem of the display apparatus is similar to that of the aforementioned quantum dot light-emitting device, so the implementation of the display apparatus can refer to the implementation of the aforementioned quantum dot light-emitting device, and repetitions are omitted here.

According to the quantum dot light-emitting device and the manufacturing method therefor, and the display apparatus provided by the embodiments of the present disclosure, the light-emitting layer having the two-phase structure of the first phases (which is a dispersed phase) and the second phases (which is a continuous phase) is manufactured, the quantum dot material is aggregated in the first phases, and it is ensured that the refractive index of the first phase is greater than the refractive index of the second phase, according to the law of refraction of light, for light emitted by the quantum dot material of the light-emitting layer, only light having an incident angle (an angle between incident light and a normal of an interface between the first phase and the second phase) less than a critical angle arcsin(n2/n1) can enter the second phase from the first phase, and thus be easily lost due to continuous propagation within the light-emitting layer; and when the incident angle is greater than or equal to arcsin(n2/n1), light can only be limited to propagate in the first phase, so it is quickly emitted from the light-emitting layer to enter other functional layers, and finally emitted from the quantum dot light-emitting device. Therefore, the light-emitting layer having the two-phase structure designed by the present disclosure can confine most of the light emitted by the quantum dot material of the light-emitting layer in the first phase where the quantum dot material is aggregated, making it tend to emit in a direction perpendicular to a plane of a film layer of the light-emitting layer, light loss caused by the waveguide mode in the light-emitting layer is reduced, the light extraction efficiency of the QLED device is improved, and the external quantum efficiency of light emission of the QLED device is finally improved. In addition, since aggregates of the quantum dot material within the first phase in the designed light-emitting layer are separated from each other, exciton quenching or interaction between other excitons caused by energy transfer among the quantum dot materials can be effectively reduced, non-radiative recombination paths of excitons can be reduced, the light-emitting quantum yield of the quantum dot light-emitting device can be improved, and the external quantum efficiency of the QLED device can be further improved.

Although the preferred embodiments of the present disclosure have been described, those skilled in the art can make additional changes and modifications to these embodiments once they know the basic inventive concepts. Therefore, the appended claims are intended to be explained as including the preferred embodiments and all changes and modifications falling within the scope of the present disclosure.

Obviously, those skilled in the art can make various changes and modifications to the embodiments of the present disclosure without departing from the spirit and scope of the embodiments of the present disclosure. Thus, if these changes and modifications of the embodiments of the present disclosure fall within the scope of the claims of the present disclosure and their equivalents, the present disclosure is also intended to include these changes and modifications.

1. A quantum dot light-emitting device, comprising:
an anode and a cathode which are oppositely disposed;
a light-emitting layer between the anode and the cathode;
a hole transport layer between the anode and the light-emitting layer; and
an electron transport layer between the cathode and the light-emitting layer;
wherein
the light-emitting layer comprises: a plurality of first phases independent from each other, and a second phase between the first phases; and
the first phase comprises a first polymer and a quantum dot material.

2. The quantum dot light-emitting device according to claim 1, wherein the second phase comprises a second polymer, and a refractive index of the first phase is greater than a refractive index of the second phase.

3. The quantum dot light-emitting device according to claim 1, wherein the anode or the cathode is a reflection electrode, and a refractive index of the hole transport layer and a refractive index of the electron transport layer both are approximately same as a refractive index of the second phase.

4. The quantum dot light-emitting device according to claim 1, wherein a material of the second polymer is same as a material of the hole transport layer, or a material of the second polymer is a hole transport material, or the second polymer is doped with a material that facilitates hole transport; and
the quantum dot light-emitting device further comprises an electron blocking layer between the light-emitting layer and the electron transport layer.

5. The quantum dot light-emitting device according to claim 4, wherein the material of the second polymer comprises poly(9,9-dioctylfluorene-co-N-(4-butylphenyl)diphenylamine), poly[N,N′-bis(4-butylphenyl)-N,N′-bis(phenyl)-benzi], polyphenylene vinylene or poly(9-vinylcarbazole); or
a doping material in the second polymer comprises 4,4′-bis(N-carbazole)-1,1′-biphenyl.

6. The quantum dot light-emitting device according to claim 4, wherein a material of the electron blocking layer comprises polyethylene, polypropylene, polytetrafluoroethylene, polycarbonate, polyamide, polymethyl methacrylate, alumina or silica.

7. The quantum dot light-emitting device according to claim 1, wherein a material of the second polymer is same as a material of the electron transport layer, or a material of the second polymer is an electron transport material, or the second polymer is doped with a material that facilitates electron transport; and
the quantum dot light-emitting device further comprises a hole blocking layer between the light-emitting layer and the hole transport layer.

8. The quantum dot light emitting device according to claim 7, wherein a doping material in the second polymer comprises 4,7-diphenyl-1,10-phenanthroline, 1,3,5-tris(1-phenyl-1H-benzimidazol-2-yl)benzene, 2,8-bis(diphenylphosphoryl)dibenzofuran, and 1,3,5-tris[(3-pyridyl)-3-phenyl]benzene.

9. The quantum dot light-emitting device according to claim 7, wherein a material of the hole blocking layer comprises polyethylene, polypropylene, polytetrafluoroethylene, polycarbonate, polyamide, polymethyl methacrylate, alumina or silica.

10. The quantum dot light-emitting device according to claim 1, wherein the second phase further comprises nanoparticles, and the nanoparticles are configured to generate localized surface plasmon resonance under irradiation by light of a preset wavelength to.

11. The quantum dot light-emitting device according to claim 10, wherein the nanoparticle is a metal nanoparticle, the light-emitting layer has a plurality of sub-pixels of different light-emitting colors, each of the sub-pixels comprises quantum dot materials of a same color, and quantum dot materials of different colors correspond to different sizes of the metal nanoparticle.

12. The quantum dot light-emitting device according to claim 11, wherein the light-emitting layer comprises a first sub-pixel emitting red light, a second sub-pixel emitting green light and a third sub-pixel emitting blue light;
the first sub-pixel comprises a red quantum dot material, the second sub-pixel comprises a green quantum dot material, and the third sub-pixel comprises a blue quantum dot material; and
a particle size of a metal nanoparticle to which the red quantum dot material corresponds, a particle size of a metal nanoparticle to which the green quantum dot material corresponds, and a particle size of a metal nanoparticle to which the blue quantum dot material corresponds decrease sequentially.

13. The quantum dot light-emitting device according to claim 10, wherein a material of the nanoparticle comprises at least one of Ag, Au, Pt, Pd, Cu or Al.

14. The quantum dot light-emitting device according to claim 1, wherein a material of the second polymer comprises a crosslinked polymeric material or a polymeric material with a melting point greater than a preset value.

15. The quantum dot light-emitting device according to claim 1, wherein a cross-sectional shape of the first phase comprises a square, an inverted trapezoid or a curved surface shape along a direction perpendicular to the cathode.

16. The quantum dot light-emitting device according to claim 1, wherein the quantum dot material is a hydrophobic material, the first polymer is a hydrophobic material, and the second polymer is a hydrophilic material; or
the quantum dot material is a hydrophilic material, the first polymer is a hydrophilic material, and the second polymer is a hydrophobic material.

17. The quantum dot light-emitting device according to claim 16, wherein the quantum dot material has a hydrophobic ligand, wherein the hydrophobic ligand comprises a coordination group that coordinates with the quantum dots, and an alkan group connected with the coordination group; and the first polymer comprises polystyrene, and the second polymer comprises polyethylene oxide, polymethyl methacrylate, polyacrylate or polyamide; or
the quantum dot material has a hydrophilic ligand, wherein the hydrophilic ligand comprises a coordination group that coordinates with the quantum dots, an alkane group connected with the coordination group, and a hydrophilic group connected with the alkane group, wherein the hydrophilic group comprises hydroxy, amino, mercapto, carboxyl or a sulfonic acid group; and the first polymer comprises polyethylene oxide, polymethyl methacrylate, polyacrylate or polyamide, and the second polymer comprises polyolefin or polystyrene.

18. The quantum dot light-emitting device according to claim 1, wherein in the first phase, the quantum dot material is bonded to at least part of the first polymer by coordination bonds; and
the second polymer and the quantum dot material are unable to be subjected to coordination binding.

19. The quantum dot light-emitting device according to claim 18, wherein the first polymer comprises a side chain having hydroxy, carboxyl, amino, or mercapto.

20. A manufacturing method for the quantum dot light-emitting device according to claim 1, comprising:
forming an anode and a cathode which are oppositely disposed;
forming a light-emitting layer between the anode and the cathode;
forming a hole transport layer between the anode and the light-emitting layer; and
forming an electron transport layer between the cathode and the light-emitting layer; wherein
forming the light-emitting layer comprises:
dissolving a first polymer and a second polymer in a preset solvent to obtain a solution of the first polymer and the second polymer;
adding a quantum dot material to the solution of the first polymer and the second polymer to be completely mixed to prepare a mixed solution of the first polymer, the second polymer and the quantum dot material; and
forming a film layer of the mixed solution on a front film layer, and volatilizing the solvent to form a light-emitting layer having the plurality of first phases, and the second phase between the first phases.

21. (canceled)
